(19) United States
(12) Patent Application Publication
(10) Pub. No.: US 2015/0368831 A1
(43) Pub. Date: Dec. 24, 2015

(54) SYSTEMS AND METHODS FOR AUTOMATED PRODUCTION OF MULTI-COMPOSITION NANOMATERIAL

(71) Applicant: King Abdullah University of Science and Technology, Thuwal (SA)

(72) Inventors: Tao Wu, Thuwal (SA); Guodong Li, Thuwal (SA)

(21) Appl. No.: 14/742,932

(22) Filed: Jun. 18, 2015

Related U.S. Application Data
(60) Provisional application No. 62/013,728, filed on Jun. 18, 2014.

(51) Int. Cl. C30B 25/14; C30B 29/60; C30B 25/10; C30B 25/12

(52) U.S. Cl. CPC C30B 25/14; C30B 25/12; C30B 29/60; C30B 25/10

(57) ABSTRACT

Various methods and systems are provided for production of nanowires or other nanomaterials. In one example, among others, a system includes a furnace configured to heat at least a portion of a tube, a material feeder coupled to a first end of the tube, and a vacuum pumping system coupled to a second end of the tube. The material feeder can include a source material manipulator that can position a source material in a fixture of a feeder arm and a linear manipulator that can extend the fixture into the tube, where it can be heated to produce a precursor vapor that can be used to form a nanomaterial on a substrate. In another example, a method includes extending a fixture holding source material into a furnace tube, drawing a precursor vapor produced from the source material across a substrate in the furnace tube, and forming nanomaterial on the substrate.

### CROSS REFERENCE TO RELATED APPLICATIONS

This application claims priority to, and the benefit of, co-pending U.S. provisional application entitled “Systems and Methods for Automated Production of Multi-Composition Nanowire” having Ser. No. 62/013,728, filed Jun. 18, 2014, which is hereby incorporated by reference in its entirety.

### BACKGROUND

Semiconductor nanowires represent a diverse class of nanomaterials whose synthetically tunable structural, electronic, and optical properties have enabled active nanodevices including high-performance field-effect transistors, ultrasensitive biological probes, and solar cells and photonic devices with tunable optical spectra. Enhanced synthetic control of the morphology, crystal structure, and composition of nanostructures can drive advances in nanoscale devices. For example, synthetically tuned and modulated properties of semiconductor nanowires can lead to further advances in nanotransistor, nanophotonic, and thermoelectric devices.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a perspective view of an example of an apparatus that utilizes vapor transport growth to produce nanowires in accordance with various embodiments of the present disclosure.

FIG. 2 is a graphical representation of vapor-liquid-solid (VLS) nanowire growth on a substrate in accordance with various embodiments of the present disclosure.

FIG. 3 is a graphical illustration of an example of the VLS nanowire growth in the apparatus of FIG. 1 in accordance with various embodiments of the present disclosure.

FIGS. 4A and 4B are top cross-sectional views of an example of the apparatus of FIG. 1 in accordance with various embodiments of the present disclosure.

### DETAILED DESCRIPTION

Disclosed herein are various examples related to production of nanowires or other nanomaterials. An automated apparatus for nanowire growth with multiple sources can advance the synthesis of multi-component nanomaterials. Nanowires are the most investigated nanomaterial and have potential applications in electronics, solar cells, sensors and other fields. Reference will now be made in detail to the description of the embodiments as illustrated in the drawings, wherein like reference numbers indicate like parts throughout the several views.

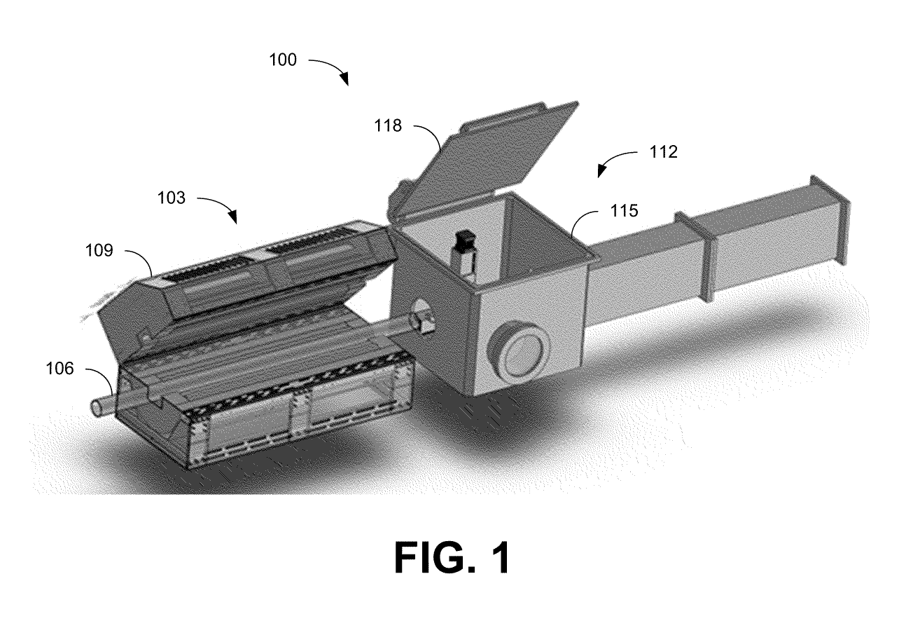

Referring to FIG. 1, shown is a perspective view of an apparatus 100 that utilizes vapor transport growth to produce nanowires under controlled temperature and pressure conditions. The apparatus 100 allows for the automated production of multicomponent (or multi-composition) nanowires from multiple source materials, without breaking the system vacuum. While this disclosure discusses the production of nanowires, the systems and methods can also be applied to the production of other nanomaterials. The apparatus 100 includes a tube furnace 103 that has a furnace tube 106 that extends through a single-zone or a multi-zone oven 109. The furnace tube 106 extends from a first end to a second end, passing through the length of the oven 109. The furnace tube 106 forms a reaction chamber in which the nanowires can be grown on a substrate located in the furnace tube 106. The heating of one or more portions of the furnace tube 106 can be controlled by the single-zone or multi-zone oven 109.

The apparatus 100 also includes a material feeder 112 that is coupled to the first end of the furnace tube 106. The second end of the furnace tube 106 is coupled to a vacuum pumping system (not shown) that maintains a vacuum, at a predefined pressure, within the furnace tube 106 and the housing 115 of the material feeder 112. A vacuum seal or connector between the furnace tube 106 and the housing of the material feeder 112 can be used to prevent leakage and thereby maintain the operating pressure within the furnace tube 106 and housing 115. With the source material positioned within the furnace tube 106, a carrying (or carrier) gas can be drawn through the furnace tube 106 from the material feeder 112 by the vacuum pumping system for formation of nanowires or other nanomaterial.

The housing 115 of the material feeder 112 encloses an automated setup for manipulation of the source material. A cover 118 provides access to the inside of the material feeder housing 115 for adding and/or removing source material. The cover 118 can be sealed to maintain the vacuum pressure within the housing during operation of the apparatus 100. The automated setup allows for different source materials to be positioned within the furnace tube 106 during various stages of the nanowire formation. In this way, the automated synthesis of multi-component nanomaterial can be accomplished while maintaining the vacuum environment of the apparatus 100.

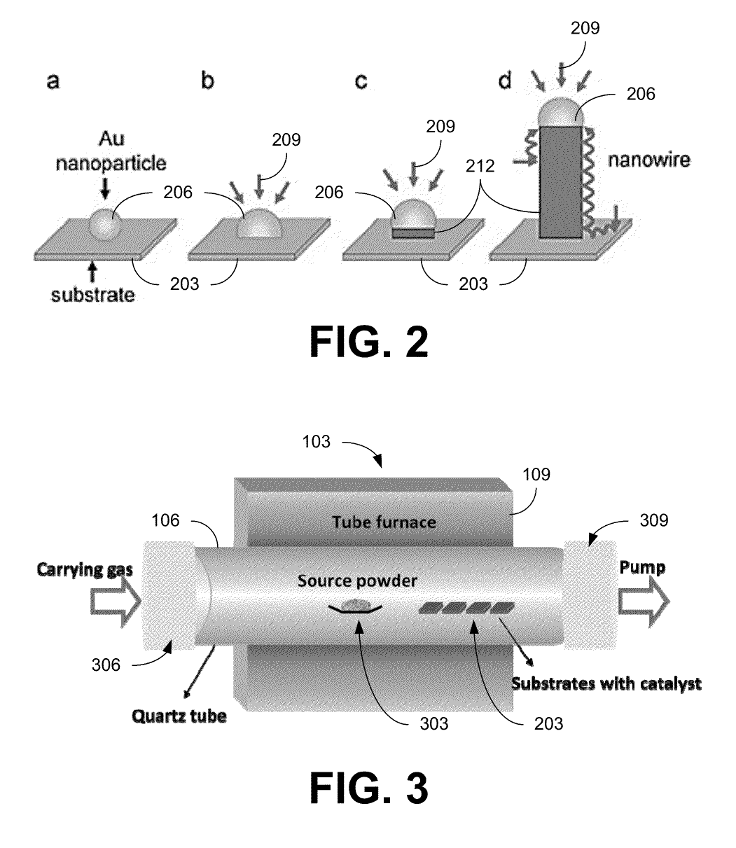

Referring to FIG. 2, shown is a graphical representation of vapor-liquid-solid (VLS) nanowire growth on a substrate 203. Initially, liquid nanodroplets 206 of an appropriate catalyst material (e.g., gold, nickel, copper—Au, Ni, Cu) are formed on the substrate 203 as illustrated in FIG. 2(a). The substrate 203 can be formed of, e.g., aluminum oxide (Al₂O₃) or other appropriate material such as silicon (Si) or glass. A growth precursor (e.g., zinc—Zn) is supplied as a gas and absorbed 209 by the catalyst nanodroplets 206 as illustrated in FIG. 2(b). The liquid nanodroplets 206 of the catalyst material act as seeds for nanowire growth. The targeted nanowire material 212 (e.g., zinc oxide—ZnO) precipitates out at the interface between the catalyst droplet 206 and the substrate 203 as illustrated in FIG. 2(c). While the growth precursor continues to be supplied, nanowire material 212 continues to precipitate out at the interface between the catalyst droplet 206 and the previously precipitated nanowire material 212, extending the length of the nanowire as illustrated in FIG. 2(d). Further discussion of VLS is provided in “Vapor-liquid-solid mechanism of single crystal growth” by R. S. Wagner and W. C. Ellis (Applied. Physics Letters, vol. 4, no. 5, pp. 89-90, March 1964) and “The vapor-liquid-solid mechanism of crystal growth and its application to silicon” by R. S. Wagner and W. C. Ellis (Trans. of the Metallurgical Society of AIME, vol. 233, pp. 1053-1064, June 1965), both of which are hereby incorporated by reference in their entirety.

In the apparatus 100 of FIG. 1, the process of nanowire growth involves heating a certain amount of source material at the center of the tube furnace 103. The vapor generated from the source material is transported by the carrier gas to a downstream position in the furnace tube 106, where the nanowires grow on one or more catalyst-covered substrates. The furnace tube 106 can be quartz, ceramic or other appropriate material or combination of materials to handle the environmental conditions of the tube furnace 103 when operating and to reduce or eliminate contamination of the synthesized nanowires or other nanomaterial.

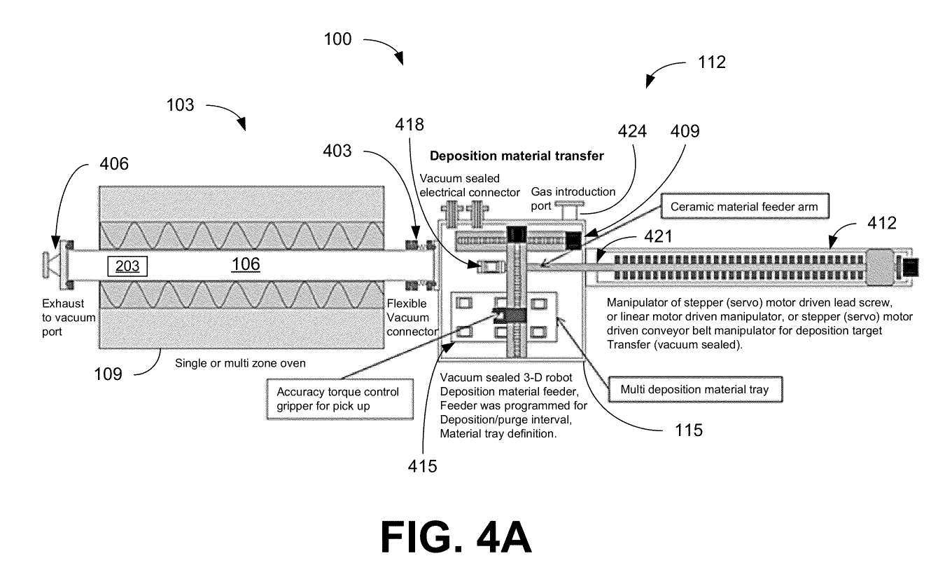

FIG. 3 is a graphical illustration of an example of the VLS nanowire growth in the apparatus 100 of FIG. 1. The furnace tube 106 is maintained at the predefined high temperature (e.g., in a range of about 300° C. to about 1100° C., or about 500° C. to about 900° C.) and pressure (e.g., in a range of about 1 mbar to about 100 mbar). These conditions vaporize the source material 303, which generally is a powder, to form the precursor vapor. The carrying (or carrier) gas 306 carries the precursor vapor along the furnace tube 106 to the location of the one or more substrates 203, where the nanowire growth takes place under the catalyst droplets 206 as illustrated in FIG. 2. The carrying (or carrier) gas 306 can be supplied to a first end of the furnace tube 106 via the material feeder 112. The carrying (or carrier) gas 306 can be a gas or a mixture of gases such as, e.g., oxygen (O₂), argon (Ar), and/or other inert gas (having a high purity), that are suitable for the formation of the nanowires. The exhaust gas 309, including the carrying (or carrier) gas 306 and the remaining precursor vapor, is removed from the second end of the furnace tube 106 by the vacuum pump system.

In some implementations, the source material (or powder) 303 may be coated with the catalyst as described in U.S. Patent Publ. No. 2010/0202952 (“Nanowire synthesis from vapor and solid sources” by Zhang et al.), which is hereby incorporated by reference in its entirety. Heating of the catalyst coated source material in the tube furnace 103 produces a vapor including the catalyst and the precursor, which facilitates nanowire growth on one or more substrates 203. In other implementations, catalyst drops 206 can be formed on the substrate(s) 203 by initially vaporizing a catalyst material and dispersing the catalyst nanoparticles on the substrate(s) 203 before putting the substrates into the furnace tube. In some embodiments, the catalyst material may be patterned on the substrate to provide for different nanomaterial geometries or patterns.

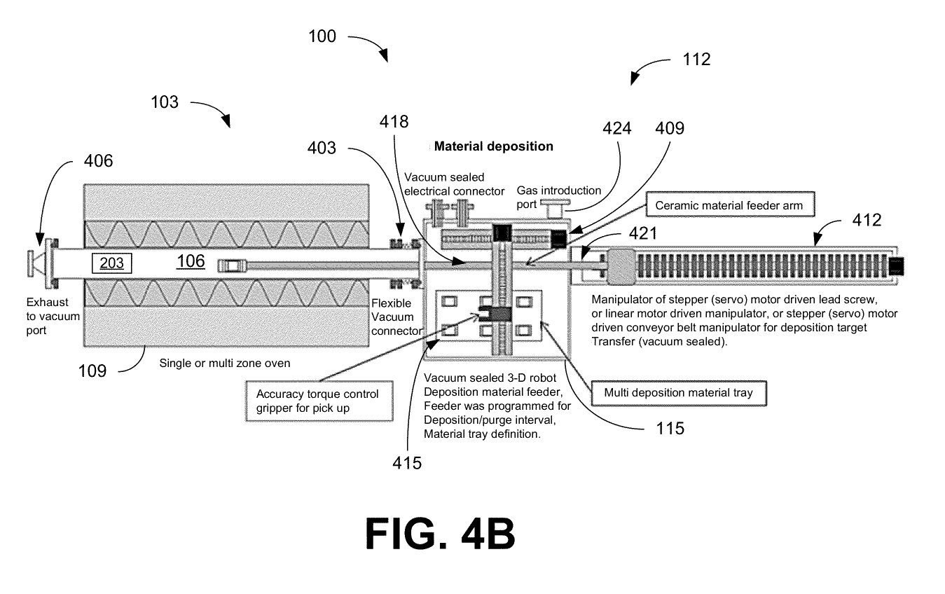

Referring next to FIGS. 4A and 4B, shown are top cross-sectional views illustrating an example of the apparatus 100 of FIG. 1. The apparatus 100 of FIG. 4A includes the tube furnace 103 with the material feeder 112 coupled to a first end of the furnace tube 106 by a flexible vacuum connector (or seal) 403. A vacuum pump system is coupled to a second end of the furnace tube 106 by an exhaust port 406. The housing 115 of the material feeder 112 encloses a source material manipulator 409 and a linear manipulator 412. The source material manipulator 409 can be configured to obtain one of a plurality of source materials 303 (FIG. 3) from, e.g., a deposition tray 415 and position it in a fixture 418 mounted at a distal end of a feeder arm 421 of the linear manipulator 412. For example, four to six different kinds of solid powder sources 303 can be used, including different oxides (e.g., ZnO, SnO₂, In₂O₃, and/or MgO) and/or chalcogenides (e.g., ZnS, ZnTe, CdS, and/or GeTe), which can be mixed with reducing graphite powder if needed. In some implementations, catalysts and/or catalyst coated source materials may also be used and manipulated.

The source material manipulator 409 can be a four-axis manipulator with a gripper that transports the source material 303 between a storage location in the material feeder 112 (e.g., in the deposition tray 415) and the fixture 418. Accuracy torque control can be used to pick up, reposition, and set down the source material 303 (or a container such as, e.g., a ceramic boat that holds the source material 303) in the fixture 418 at the distal end of the feeder arm 421 of the linear manipulator 412. With the source material 303 in the fixture 418, the feeder arm 421 of the linear manipulator 412 can be extended to position the source material 303 in the furnace tube 106 for formation of the nanowires as illustrated in FIG. 4B.

The linear manipulator 412 can include a stepper motor or servo motor driven lead screw or conveyor belt or a linear motor, which can be used to extend the feeder arm 421 from the material feeder housing 115 into the furnace tube 106 or retract the feeder arm 421 from the furnace tube 106 back into the material feeder housing 115. The material feeder housing 115 may extend around the linear manipulator 412 to maintain the vacuum seal or a vacuum seal may be provided around the feeder arm 421 at the interface between the linear manipulator 412 and the material feeder housing 115 to maintain the predefined pressure in the material feeder 112 and furnace tube 106. Electrical connections into the material feeder 112 are also vacuum sealed.

The apparatus can also include a control system, which can monitor various system parameters (e.g., temperature, pressure, flow, position, etc.) and control operation of the apparatus 100 in response to one or more of the monitored parameters. For example, temperatures along the furnace tube 106 can be monitored and operation of the tube furnace 103 can be adjusted accordingly. Operation of the vacuum pump system may also be controlled to maintain the monitored furnace tube pressure at a predefined pressure and/or within predefined limits. Positioning of the source material manipulator 409 and the linear manipulator 412 can also be monitored and controlled.

The control system can be implemented using processing circuitry. In various embodiments, the processing circuitry is implemented as at least a portion of a microprocessor. The processing circuitry may be implemented using one or more circuits, one or more microprocessors, microcontrollers, application specific integrated circuits, dedicated hardware, digital signal processors, microcomputers, central processing units, field programmable gate arrays, programmable logic devices, state machines, or any combination thereof. In yet other embodiments, the processing circuitry may include one or more software modules executable within one or more processing circuits. The processing circuitry may further include memory configured to store instructions and/or code that cause the processing circuitry to execute various control functions.

Operation of the apparatus 100 to grow nanowires will now be briefly discussed with respect to FIGS. 3, 4A and 4B. Initially, one or more substrates 203 (FIG. 3) are positioned within the furnace tube 106 and the furnace tube 106 and the material feeder 112 are purged to remove potential contaminants. The substrate(s) 203 can be coated with catalyst before or after being positioned in the furnace tube 106 as was discussed above. Purified and/or controlled gases can be introduced during purging through a gas introduction port 424 in the housing 115 of the material feeder 112. After purging, the furnace tube 106 and material feeder 112 can be maintained at the predefined pressure using the vacuum pump system. The tube furnace can be heated up to the designed temperature. While maintaining the predefined pressure, formation of nanowires or other nanomaterials using multiple source materials 303 (FIG. 3) can be accomplished without breaking the vacuum seal of the apparatus 100.

With the feeder arm 421 retracted as shown in FIG. 4A, the source material manipulator 409 can be controlled to select a desired source material 303 from the deposition tray 415 and place it in the fixture 418 at the distal end of the feeder arm 421. With the source material 303 in the fixture 418, the feeder arm 421 can be extended into the furnace tube 106 until the appropriate position is reached. The single-zone or multi-zone oven 109 can be controlled to heat up the appropriate portion of the furnace tube 106 to vaporize the source material 303 to form the precursor vapor. Carrying (or carrier) gas 306 (FIG. 3) can be provided through the gas introduction port 424 to carry the precursor vapor to the substrate(s) 203, where it interacts with the catalyst (e.g., catalyst drops 206 of FIG. 2) on the substrate(s) 203 to grow the nanowires 212 (FIG. 2) or other nanomaterial. The exhaust gas 309 is removed from the furnace tube 106 by the vacuum pump system through the exhaust port 406.

When synthesis of the nanowires with the source material 303 is finished, the feeder arm 421 can be retracted back into the material feeder housing 115, and the container, which may hold any unused source material 303, is returned to the deposition tray 415 by the source material manipulator 409. A second source material 303 may then be placed in the fixture 418 using the source material manipulator 409 for continued nanowire growth. During this exchange of source materials 303, the furnace tube 106 may be purged again. The feeder arm 421, with the second source material, may then be extended to the desired position within the furnace tube 106. The tube furnace 103 can be maintained at the same temperature or adjusted to a different temperature and provided with carrying (or carrier) gas 306 to continue the nanowire synthesis. The process can be repeated multiple times using combinations of the same or different source materials 303 (e.g., second, third, fourth, fifth or more source materials). Movement of the source material manipulator 409 and the linear manipulator 412, as well as a deposition tray definition, can be programmed for deposition and purge intervals during operation.

In some embodiments, the apparatus 100 may include a plurality of linear manipulators 412 that may be extended from the material feeder 112 into the furnace tube 106. The source material manipulator 409 can be controlled to position catalysts and/or source materials 303 in the fixture 418 of the various linear manipulators 112 to coat substrate(s) with catalyst and/or grow nanowires. In some cases, multiple source materials 303 or a combination of catalyst and source materials 303 may be positioned within the furnace tube 106 using the linear manipulators 412. A multi-zone oven 109 allows for heating at different temperatures at different locations along the furnace tube 106, allowing for vaporization of different materials at the same time. Other variations are also possible.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A system for producing nanomaterials, comprising:
a furnace including a tube, the furnace configured to heat at least a portion of the tube to a predefined temperature;
a material feeder coupled to a first end of the tube, the material feeder comprising:
a source material manipulator configured to obtain a source material and position the source material in a fixture at a distal end of a feeder arm; and
at least one linear manipulator configured to extend the feeder arm to position the fixture in the portion of the tube, where the source material forms a precursor vapor when heated at the predefined temperature; and
a vacuum pumping system coupled to a second end of the tube, the vacuum pumping system configured to maintain a predefined pressure in the tube and material feeder while the precursor vapor forms a nanomaterial on a substrate in the furnace tube.

2. The system of claim 1, wherein the nanomaterial is nanowire.

3. The system of claim 1, wherein the precursor vapor is transported from the portion of the tube to the substrate by a carrier gas.

4. The system of claim 1, wherein the source material is obtained from a deposition tray holding the source material.

5. The system of claim 4, wherein the source material manipulator is further configured to:
remove the source material from the fixture with the feeder arm retracted into the linear manipulator; and
return the source material back to the deposition tray.

6. The system of claim 5, wherein the source material manipulator is further configured to obtain a second source material and position the second source material in the fixture.

7. The system of claim 1, wherein the source material manipulator is further configured to position a plurality of source materials in the fixture.

8. The system of claim 7, wherein the plurality of source materials form the precursor vapor when heated.

9. The system of claim 1, wherein the at least one linear manipulator comprises a first linear manipulator configured to extend the feeder arm to position the fixture in the portion of the tube and a second linear manipulator configured to extend a second feeder arm to position a second fixture in a corresponding portion of the tube.

10. The system of claim 9, wherein the first and second fixtures are collocated in the tube.

11. The system of claim 9, wherein the first and second fixtures are positioned in different portions of the tube.

12. The system of claim 11, wherein the furnace is configured to heat the corresponding portion of the tube, where the second fixture is positioned, to a second predefined temperature.

13. A method, comprising:
extending, via a feeder arm of a material feeder, a fixture to a defined location in a furnace tube, the fixture holding a source material;
heating a portion of the furnace tube to a predefined temperature, the portion of the tube corresponding to the defined location in the furnace tube;
drawing a precursor vapor across a substrate in the furnace tube, the precursor vapor produced from the source material by heating the portion of the furnace tube; and
forming nanomaterial on the substrate, where the nanomaterial is formed by an interaction of the precursor vapor with a catalyst.

14. The method of claim 13, further comprising:
positioning the substrate in the furnace tube; and
purging the furnace tube and the material feeder with a gas to remove potential contaminants prior to extending the fixture.

15. The method of claim 14, wherein the furnace tube and the material feeder are maintained under a defined vacuum pressure after purging.

16. The method of claim 15, further comprising:
selecting, via a source material manipulator, the source material from a plurality of source materials available in the material feeder; and
positioning the source material in the fixture.

17. The method of claim 13, further comprising:
retracting the fixture from the furnace tube;
removing any remaining source material from the fixture;
extending the fixture to a corresponding location in a furnace tube, the fixture holding a second source material; and
drawing a second precursor vapor across the substrate in the furnace tube, the second precursor vapor produced from heating the second source material, the second precursor vapor interacting with the catalyst to form the nanomaterial.

18. The method of claim 17, further comprising purging the furnace tube and the material feeder with gas after retracting the fixture from the furnace tube.

19. The method of claim 13, further comprising:
extending, via a second feeder arm of the material feeder, a second fixture to a corresponding location in the furnace tube, the fixture holding a second source material; and
concurrently heating the source material and the second source material to produce the precursor vapor.

20. The method of claim 19, wherein the source material is heated by a first portion of the furnace tube and the second source material is heated by a second portion of the furnace tube.
